(19) United States
(12) Patent Application Publication
(10) Pub. No.: US 2014/0167677 A1
(43) Pub. Date: Jun. 19, 2014

(54) LONG-LASTING, HIGH POWER DENSITY AND FLEXIBLE PHOTOVOLTAIC (PV) CRYSTALLINE CELL PANEL, A METHOD FOR MANUFACTURING THE SOLAR PANEL AND INTEGRATED SOLAR POWER GENERATION AND SUPPLY SYSTEM

(71) Applicant: Harold E. Voelkner, Hong Kong (CN)

(72) Inventor: Harold E. Voelkner, Hong Kong (CN)

(21) Appl. No.: 14/131,735

(22) PCT Filed: Jul. 12, 2012
(86) PCT No.: PCT/US2012/046504

§ 371 Date: Mar. 10, 2014

Related U.S. Application Data
(63) Continuation-in-part of application No. PCT/US2011/043880, filed on Jul. 13, 2011.

(51) Int. Cl. H01L 31/048; H02J 7/35; H02S 30/20

(52) U.S. Cl. CPC H01L 31/048; H01L 31/045; H02J 7/35
USPC 320/101; 136/251; 438/66

(57) ABSTRACT

No glass, thin, low weight, portable/semi-portable solar PV panels are described. They are not for larger, permanently fixed installations, but are for solarizing outdoor consumer/industrial products. Thin (<3-10 mm), high power density, solar PV panels, custom designed for each target product using commercially available, highest efficiency range (18-23%) solar PV crystalline cells, which are encapsulated without glass, by long life (10-15+ years), flexible and high transparency encapsulation materials. This new technology allows manufacturing of solar PV crystalline cell panels and systems that are surface mounted on flat- or multi-curved surfaces. The thin PV crystalline cell panels have these advantages: rugged, portable, flexible or rigid, lightweight and long-life (10-15+ years). The majority of these thin and flexible PV crystalline panel applications are mostly of mini-panel size (0.01-100 Wp) but large sized (over 500 Wp) panels can be made and mounted on multi-curved surfaces on electric vehicles (land, water, and air).

### BACKGROUND OF THE INVENTION

1. Field of the Invention

Most specifically, the present invention relates to a growing subcategory of solar PV power systems:—to thin and lightweight, highest commercially available power density, rugged and portable, long-life, flexible or rigid solar Photovoltaic (PV) crystalline cell panels and systems ranging from mini-panels (0.01-100 Wp) using laser cut standard cells into mini cells and assembled into mini panels. Further, the present invention relates to a method for manufacturing the solar panel and integrated solar power generation and supply system. Recently thin and flex panels (over 500 Wp) were developed, which are currently designed and tested to directly supply electrical power to a multitude of large consumer or industrial, electronic/electrical devices (HEV-EVs), or indirectly through rechargeable power storage devices when-ever-needed or for night time use.

2. Description of Prior Art and its Problems

It is a matter of record that, since the start of commercial production of PV solar devices in the late 1970s in the USA, and still now in the whole world, over 90 percent of all solar modules and systems are mass produced, conventional, standard sized crystalline cell modules (100-400+ Wp) which were designed solely for larger scale, grid-connect power generation fields or farms. They are made with bulky and heavy glass covers and big aluminum frames and are permanently installed for lasting over 20+ years. They were, and still are: glass breakable and non-portable, i.e. totally unsuitable for the growing need for thin, long life, light weight, high power density, mini- to max-panels, custom designed for ‘products-specific-solarizing’ the ‘power supply of outdoor’ electric—electronic consumer/industrial devices.

One necessary clarification that must be emphasized here is that there are two distinctly different application targets for solar power devices:
for large scale systems, both grid-connected and stand alone (90% of all solar devices production) versus.
for the relatively very small to large size, low voltage consumer/industrial outdoor devices, ranging from pocket solar power packs for smart phones to recently the large HEV-EVs for personal and public transport on land, water, and air.

These two application targets require significantly different material, design, production and evaluation technologies which also result in different measurement procedures/targets, technical standards, jargon and so on.

There are also different definitions for ‘solar modules’ versus ‘solar panels’:
A solar ‘module’ is a large mass produced standard device with few different models and sizes, designed and installed mostly in large numbers in >1 MWp fields or farms.
(2) A solar ‘panel’ is defined and tailor-designed for each specific electric/electronic consumer/industrial device of many sizes and shapes, and produced in a wide range of numbers from a few to many of each. This requires not only a very flexible, ‘made to order’ production technology, equipment and management system, but also a different, wider range of necessary adaptations and inventions, but as well as field experience in this less known (<10%) subcategory of PV solar technology.

The need for small, thin solar panels for consumer/industrial products also started small but successfully in the 1970s in the form of very small solar-thin-film (a-Si) panels in indoor (low light) desk calculators. This also led in the middle 1980s to the first solar powered outdoor product,—the 1^{st} solar garden light with a 1^{st} mass-produced larger, small a-Si mini-panel (1.8 Wp). It had an explosive sales success of more than 400K units in 2 years (1986-1987). But an equally fast implosion in “1988-1989” with 400K units left unsold in stock after the solar-thin-film-panel-efficiency fell from 5 to 3% in the 1^{st} 3 months in the sun (daylight) and ceased to function within the 1^{st} year.

In 1989, Chronar USA (the developer/maker of the a-Si panels and garden lights) went bankrupt and the garden-light remaining stock was fire-sold over the following 2 years at US $ 0.20 to the dollar,—some of the a-Si panels stock sold for less.

The Chonar contract-production manager in Hong Kong, Sun Power Systems Ltd (SPS), successfully developed a thin, crystalline PV replacement panel for the garden light which worked beautifully, but the a-Si failure and the fire sale had totally ruined the new, worldwide market for garden lights for the next 5 years.

However the thin, high power density mini panel production was started, SPS was shelved and a new company Sol-Lite Mfg. Ltd was starting the production & promotion of thin, long life, high power density, crystalline mini-panels and designing the solarization of battery or low-voltage grid power operated consumer and industrial devices in 1990. Five years later, Sol-Lite Mfg. Ltd solarized a low voltage Malibu garden lights in the USA, generating a US $ 2 million order and the garden light market with thin, crystalline solar panels took off.

The pent-up demand for small, thin, light weight, reliable solar panels & products initially made the production & supply of thin, long life, reliable panels made by Sol-Lite Mfg. Ltd grow quickly in the 1990s, but it also caused a rapid growth of ‘short life’, thin, light weight, potted panels. Because the polyurethane potting technology is difficult and complicated to implement, a none-polyurethane clear plastic was and still is used,—but with a critical and severe shortcoming—it is not UV resistant. But because these were cheaper to make, they were preferred by the still innocently, solar inexperienced, high demand market of the early 2000s.

Most of the current thin crystalline panels have a short life span of <1 to 2 yrs because they are encapsulated using unsuitable, short life materials such as epoxy and plastics which are not outdoor UV nor weather resistant. These ‘cheaper’ PV mini-panels are widely used in low quality, low priced consumer products with a similar life span. This low cost panel fabrication method results in of over 20 years solar cell waste and environmental pollution due to the fact that the conventional quality PV crystalline solar cell typically has a life span of more than 25 years. Not only does this mean an average of 92% loss (23+ years) of the potential productive life span of crystalline solar cells, but also results in repeated heavy pollution by replacing all other solar panel content materials.

Current thin film amorphous solar PV cells and panels still have a too low solar cell efficiency ranging from <5 to 14% and consequently low panel power density ranging from only ˜3 to 10 mW/cm² per panel. This is very insufficient for the limited area available for the high power needs for installing on roofs of electrical vehicles or similar applications.

Moreover, when short life solar panels are used in higher quality, longer life, higher price products, the use of these short lived solar panels causes even greater loss of product life years and materials as well as losses in users money, satisfaction and the product's reputation. But the supply of thin, long lasting (>10 yrs), high power density, light weight and flexible crystalline PV solar mini and large panels is currently very low for the significantly growing worldwide demand. Hence, there is a exploding demand for providing an improved long life and flexible solar panels, which overcomes the above mentioned disadvantages.

### SUMMARY OF THE INVENTION

The main object of the present invention is to make thin, high power density solar PV panels, wherein PV crystalline cell strings are encapsulated in clear, flexible and long life encapsulating materials, having a fully functional lifespan of over 10 years. They are to be attached to semi- or fully movable objects/products for consumer or industrial use ranging from very small size (solar pocket power packs) to relatively large size (HEV-EVs for personal and public transport on land, water, and in the air).

Another object of the present invention is to provide thin, high power dense solar panels which can be encapsulated on a variety of substrate configurations for the solar PV crystalline cell strings, with flexible or rigid substrate, or even without any substrate, but simply for the proper encapsulating materials such as specific polyurethane polymers.

Further object of the present invention is: (1) to provide a method of capsulation by potting that can avoid or remove air trapped under the solar cells or inside the polyurethane, for practical volume scale mass production of the thin solar panel and (2) provide a method of encapsulation by laminating curved solar panels for attachment to multi-curved surfaces such as on HEV-EVs.

The thin, long life solar panel comprises a plurality of solar PV crystalline cells, which are connected together to form one or more solar cell strings, wherein the solar cell strings are connected together in series and/or parallel to form a solar cells system as required by panel design, wherein the solar PV crystalline cells are encapsulated in clear, flexible and durable encapsulating materials. Further embodiments of the present invention are subject of the further subclaims and of the following description, referring to the drawings.

The thin, long life solar panel comprises only commercially available highest efficiency solar PV crystalline cells, with currently efficiency ranging from 18-23% (18-23 mWp/cm² solar cell) and higher, and consequently the commercially highest power density for the solar panel, currently ranging from 16 to 21 mW/cm² of panel area.

The solar cells are laser cut into mini-cells from a standard full size cell for mini-panels (0.01-100 Wp) or used as complete full cell for max-panel (100 Wp-500+ Wp) as required by panel design for each target device.

The encapsulating material is made of a clear, flexible, UV resistant, weather-proof, space-environment suitable, long life (currently over 10 years) polyurethane or other similar materials with the same range of quality specifications. The said life span of over 10 years has been proven by having manufactured thin panels with these said materials for over 20 years with no known cases of early degradation, nor ever experienced returns as a response to our 5 year product warranty. In addition, the said solar PV crystalline panels of this invention are encapsulated by employing the potting process for flat surfaces or other processes such as vacuum lamination for curved surfaces. The potting process generally relates to the dispensing of fluid encapsulating materials such as polyurethane to cover the cell assembly 360° and seal-in the solar cells—moisture and air proof—for the purpose of protection against corrosion. Curved surfaces lamination is to enclose and seal the solar cell assembly between two sheets of clear plastic film with thermal polymer sheets of encapsulation material, such as EVA or TPU for the same purpose as for potting (see potting and lamination in a continuously updating encyclopedia such as Wikipedia).

The solar panel further comprises a plurality of outlet conducting cables, wherein the solar cells system is connected to the outlet conducting cables.

The solar panel further comprises at least one cable box to protect and house the connections between the solar cells system and the outlet conducting cables.

The solar panel may have or not have a thin edge frame, surrounding the edges of the panel as required by panel design.

The solar panel may or may not have temporary or permanent a rigid or flexible substrate.

The substrate is rigid but thin (<2-4 mm) or as required by panel design.

The solar panel, without a flexible substrate, is flexible itself, and can be bent in any direction and attached to moderately curved surfaces.

The substrate of the flexible solar panel can be a flexible sheet or tray of any appropriate flexible material for use as a substrate for encapsulated crystalline solar cell strings.

The solar panel with a rigid substrate can be attached to rigid flat surfaces or supporting frames.

The substrate can be rigid and shaped in any appropriate configuration according to design needs or end use. In addition, the panel may have a thin metal or plastic edge frame to surround the panel edges and is encapsulated together with the solar cells system.

The substrate may have a plurality of plastic or corrosion-resistant metal grommets built into the corners and/or sides of the substrate. Other materials, which are light and corrosion resistant, may also be used for the grommets. These grommets facilitate the attachment of the solar panel to its supporting device.

The functional lifespan of all the materials used in the solar panel is more than 10 years in portable or semi-portable applications.

The method for manufacturing the solar panel comprising an encapsulated solar cells system onto a temporary substrate (for a solar panel without substrate) or a permanent substrate (for a solar panel with substrate) by potting or lamination in an encapsulating material, wherein the encapsulating material is UV/weather-resistant, flexible, and clear polyurethane or similar quality polymers.

The potting method further comprising:
pre-degassing the polyurethane by heating and vacuuming before potting. vacuuming the potted solar panel to bring the air trapped under the solar cells and inside the polyurethane to the top surface right after potting, and then bubble picking.
Further bubble picking after higher temperature (60° C.) accelerated partial gelling of the potted solar panel before complete gelling and curing at a lower temperature (40° C.).

Multiple solar panels can be connected together in series and/or parallel and with energy storage devices and other essential BOS components such as bypass diodes, blocking diodes, solar controller and/or inverter etc, to form a complete solar PV power generation and supply system for directly charging or supplying power to suitable devices/equipments such as batteries/motors of an electrical or hybrid vehicle and other relevant equipments.

The above mentioned embodiments as well as the subject matter of the claims and the description may be combined with each other in any manner provided this is feasible and useful and not explicitly excluded. The foregoing, as well as additional objects, features and advantages of the invention will be more readily apparent from the following detailed description, which proceeds with reference to the accompanying drawings. The invention is explained in more detail below using exemplary embodiments which are specified in the schematic figures of the drawings, in which:

### BRIEF DESCRIPTION OF THE DRAWINGS

FIG. 1. A drawing illustrating the top view of a sample thin solar mini-panel (with a nominal power of 3 Wp for this demonstration but applicable to any size in this panel category)

FIG. 2. A drawing illustrating the perspective view of a thin solar mini-panel (with a nominal power of 3 Wp)

FIG. 3. An exploded drawing illustrating the construction of a thin solar mini-panel (with a nominal power of 3 Wp)

FIG. 4. A drawing illustrating the application of bending and integrating a thin flexible solar mini-panel (with a nominal power of 3 Wp) to the curved surface of a supporting surface.

FIG. 5. A drawing illustrating the application of integrating a thin solar mini-panel (with a nominal power of 3 Wp) to a rigid and flat surface of a substrate.

FIG. 6. A workflow diagram illustrating the process steps of encapsulation by potting of polyurethane polymer.

Skilled artisans will appreciate that elements in the figures are illustrated for simplicity and clarity and have not necessarily drawn to scale. For example, the chosen elements are only used to help to improve the understanding of the functionality and the arrangements of these elements in various embodiments of the present invention. Also, common but well understood elements that are useful or necessary in a commercial feasible embodiment are mostly not depicted in order to facilitate a less abstracted view of these various embodiments of the present invention. It will further be appreciated that certain actions and/or steps in the described method may be described or depicted in a particular order of occurrences while those skilled in the art will understand that such specificity with respect to sequence is not actually required. It will also be understood that the terms and expressions used in the present specification have the ordinary meaning as it accorded to such terms and expressions with respect to their corresponding respective areas of inquiry and study except where specific meanings have otherwise be set forth herein.

In all figures of the drawings elements, features and signals which are the same or at least have the same functionality have been provided with the same reference symbols, unless explicitly stated otherwise.

### DESCRIPTION OF EMBODIMENTS

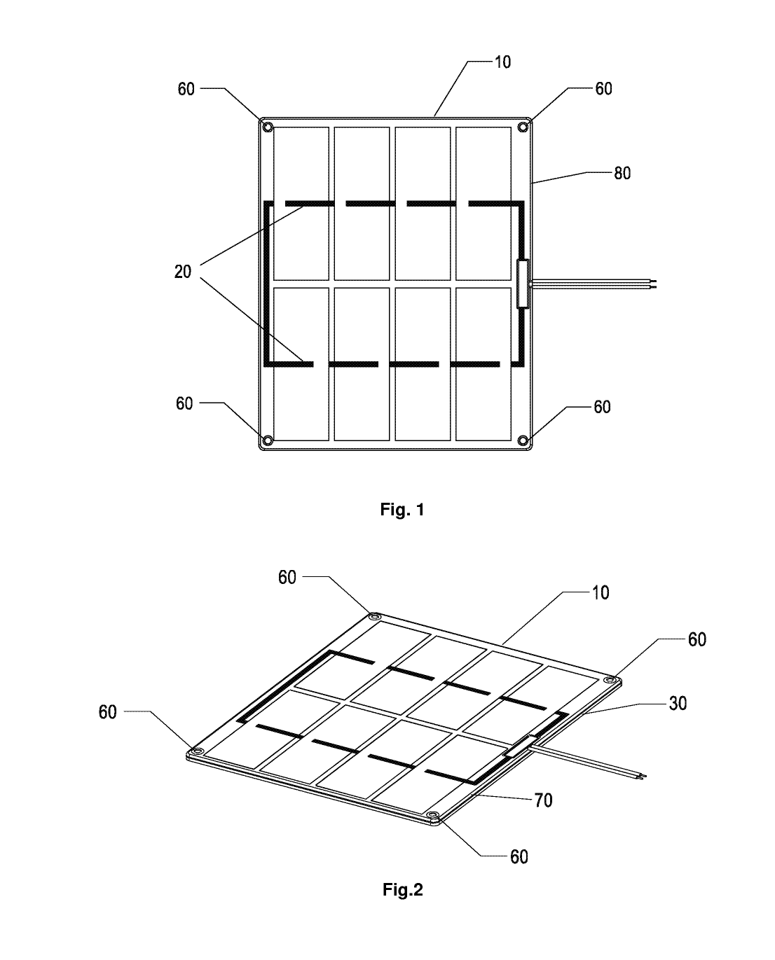

Referring to the drawings FIGS. 1 and 2, the thin solar PV crystalline cell mini panel (3 Wp) 10 of this invention comprising solar PV crystalline cells 21, which are encapsulated by a potting process in encapsulating materials 70; wherein said solar PV crystalline cells 21 may be connected together in series and/or parallel to form solar cell strings 20; wherein said encapsulating materials 70 are flexible and transparent. Preferably, the said solar PV crystalline cells 21 are of highest commercially available efficiency, (currently up to 23% and rising). The said encapsulating materials 70 are UV/weather-resistant, space environment suitable, flexible and clear such as certain polyurethanes, other polymers or other suitable alternative materials. Moreover, the lifetime of these materials must be more than 10 years.

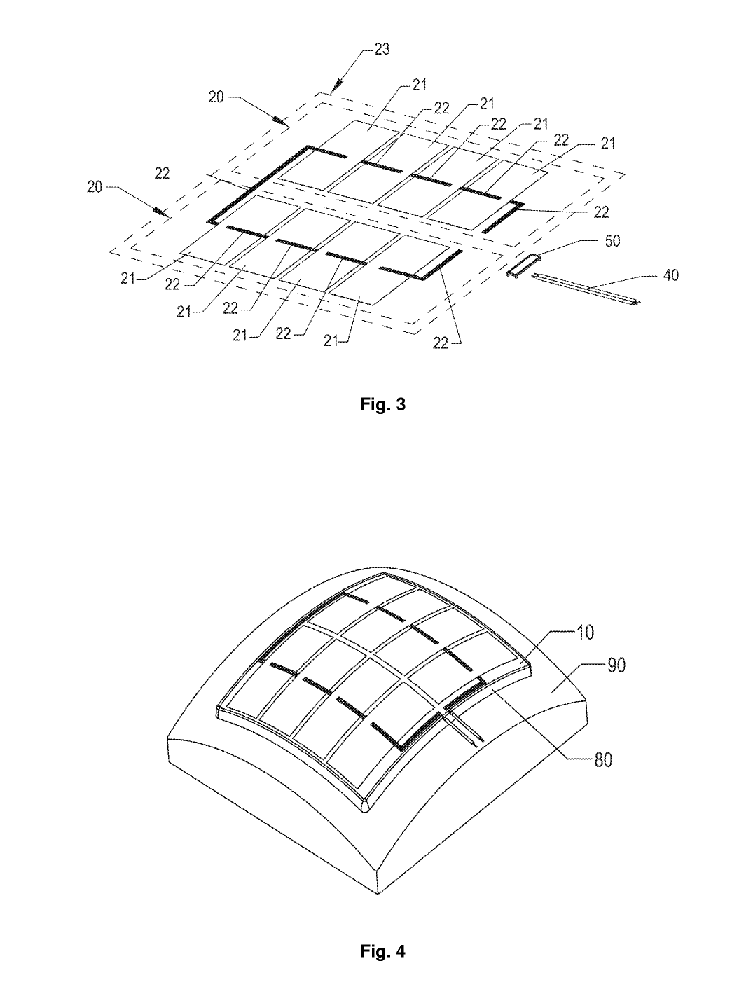

Referring to FIG. 3, the conducting ribbons 22 are used to connect the solar PV crystalline cells 21 in series and/or in parallel to form solar cell strings 20. The solar cell strings 20 are connected together in series and/or parallel to form the solar cells system 23.

Referring to FIG. 3, the solar cells system 23 are connected to the outlet conducting cables 40 for the thin solar mini-panel 10 electrical outlet. The cable box 50 is used to protect the connections between the solar cells system 23 and the outlet conducting cables 40.

Referring to FIGS. 1 and 2, a thin metal or plastic edge frame 80 surrounds the flat, rigid panel 10 edges for protecting the edges of the solar mini-panel 10. The grommets 60 are built into the corners and/or the sides of said thin solar mini-panel 10 for easy assembly or installation. The said grommets 60 are made of plastic or corrosion-resistant metal or other suitable material.

Referring to FIG. 2, the solar cells system 23, the conducting cables 40, the cable box 50, the plastic or metal edge frame 80 and the grommets 60 are encapsulated on the top of a temporary substrate or permanent flexible substrate 30 (for a thin solar flexible panel) or permanent rigid substrate 30 (for a thin solar rigid panel) by potting or other processes in UV/weather-resistant, long-lasting (currently over 10 years), flexible and transparent encapsulating materials 70.

Referring to FIGS. 2 and 5, the permanent substrate 30 can be a rigid, flat, lightweight, thin sheet or tray, which can be of any appropriate material such as metal or plastic composite and in any appropriate configuration such as rectangular, round or other suitable shapes.

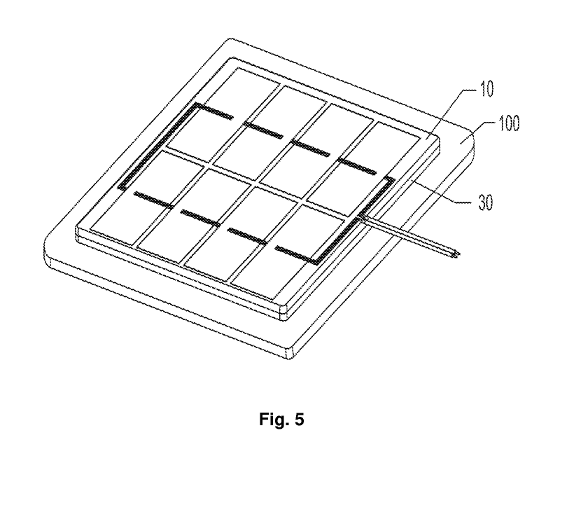

Referring to FIG. 4, the thin solar mini-panel 10 has a gasket 80 to surround the panel edges are encapsulated together with the solar cells system 23. The thin solar mini-panel 10 can be bent in any direction and attached to moderately curved surfaces 90.

Referring to FIG. 5, the thin solar mini-panel 10 is encapsulated to the top of a suitable rigid substrate 30, which can be attached on flat surfaces 100.

The thin solar mini-panel 10 made by the application of this invention is rugged and portable, flexible, lightweight, and long-lasting (currently up to or over 10 years), with highest commercial cell efficiency, currently up to 23% and rising, and consequently high panel power density, currently up to 21 mWp/cm²/panel and rising.

Multiple thin, high power density PV crystalline cell panels can be connected together in series and/or parallel, with energy storage devices and other essential BOS components such as bypass diodes, blocking diodes, solar charger controller and/or inverter, etc, to form a complete solar PV power generation and supply system for directly charging or supplying power to suitable devices/equipments such as batteries/motors of an electrical or hybrid vehicle and other equipment.

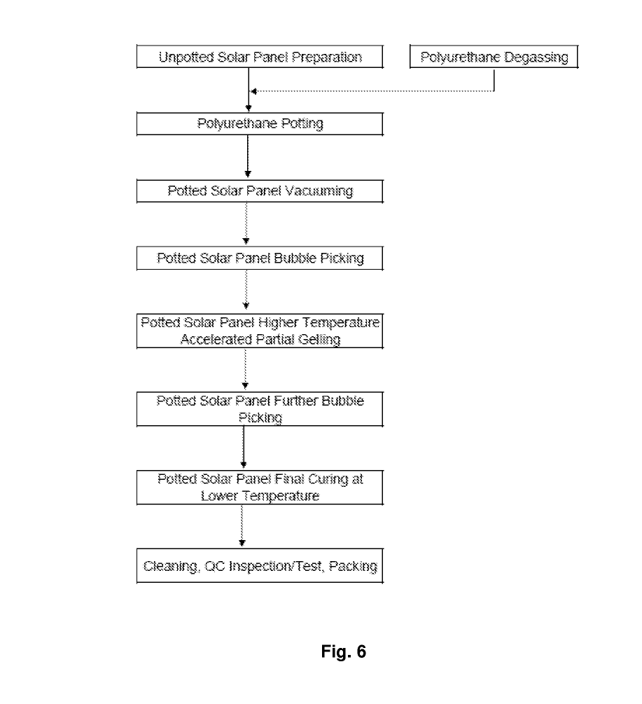

Referring to FIG. 6, the encapsulation process by potting of polyurethane polymer comprising the following steps:
a. degassing the polyurethane polymer by heating and vacuuming for removing moisture inside the polymer fluids;
b. preparing the unspotted solar panel by laying the solar cells system together with outlet conducting cables onto temporary substrate (for a solar panel without substrate) or permanent substrate (for a solar panel with substrate);
c. potting the un-potted solar panel with polyurethane polymer;
d. vacuuming the potted solar panel right after potting to bring air trapped under the solar cells to the top surface of the polyurethane polymer;
e. picking air bubbles on surface and/or inside polyurethane right after vacuuming;
f. higher temperature accelerated partial gelling of potted solar panel in an oven;
g. further picking air bubbles right after higher temperature (60° C.) accelerated partial gelling of potted solar panel;
h. final curing of potted solar panel in lower temperature (40° C.) cabinet;
i. cleaning, QC inspecting/testing, packing the potted panel.

While embodiments and applications of this invention have been shown and described above, it should be apparent to those skilled in the art, that many more modifications (than mentioned above) are possible without departing from the inventive concept described herein. The invention, therefore, is not restricted except in the spirit of the appending claims. It is therefore intended that the foregoing detailed description is to be regarded as illustrative rather than limiting and that it is understood that it is the following claims including all equivalents described in these claims that are intended to define the spirit and the scope of this invention. Nor is anything in the foregoing description intended to disavow the scope of the invention as claimed or any equivalents thereof.

The foregoing descriptions of embodiments only illustrate some essential components and process(s) of this invention in which the descriptions are concrete and detailed, but it should not be understood that these are the limitations to the scope and the protection extent of this invention. Within the conception of this invention, a technician in the art can still make some modifications and improvements, which all belong to the scope and the protection extent of this invention.

In this document, relational terms such as first and second, top and bottom, and the like may be used solely to distinguish one entity or action from another entity or action without necessarily requiring or implying any actual relationship or order between such entities or actions. Further, the terms “comprise/comprising”, “have/having”, “include/including”, “contain/containing” or any variation thereof, are intended to cover a non-exclusive inclusion, such that the process, method, article, apparatus does not include only those elements/steps but may include other elements/steps not expressly listed or inherent to such process, method, article, or apparatus. Further, the terms “a/an” are defined as one or more unless explicitly stated otherwise.

The scope and the protection extent of this invention are defined by the following claims.

### LIST OF USED REFERENCE NUMBERS

10 solar panel

20 solar cell strings

21 solar PV crystalline cells

22 conducting ribbons

23 solar cells system

30 substrate

40 outlet conducting cables

50 cable box

60 grommets

70 encapsulating material

80 edge frame or gasket added to flex panels

90 curved surface

100 flat surface

What is claimed is:

1. A thin (<3-10 mm), ‘no glass’, low weight (<30-70 g/Wp), high power density photovoltaic (PV) crystalline cell panel, comprising a plurality of solar PV crystalline cells,
which are connected together to form one or more solar cell strings,
wherein the solar cell strings are connected together in series and/or parallel to form a solar cells system as required by panel design,
wherein the solar PV crystalline cells are encapsulated in clear, flexible and durable encapsulating materials.

2. The solar panel of claim 1, wherein the solar PV crystalline cells are configured such that they comprise the highest commercially available cell efficiency (currently 18-23%) and wherein the solar panels is configured such that they comprise the highest feasible power density (16-21%).

3. The solar panel of claim 1, wherein the solar cells are cut into mini cells from standard full size cell for mini-panels (0.01-100 Wp) or wherein the solar cells are used as complete full cell for max-panel (100 Wp-500+ Wp) as required by panel design for the target solarized devices.

4. The solar panel of claim 1, wherein the solar cell encapsulating materials are fully transparent and flexible, in fluid or thin sheet form before encapsulation.

5. The solar panel of claim 1, wherein the solar cell encapsulating materials in fluid or sheet form, are UV/weather-resistant, space environment fit, and functioning for over 10 years polyurethane polymer or similar materials with similar functions and benefits.

6. The solar panel of claim 1, wherein the solar PV crystalline cells are encapsulated by a potting process or by a lamination process.

7. The solar panel of claim 1, further comprising a plurality of outlet conducting cables, wherein the solar cells system is connected to the outlet conducting cables.

8. The solar panel of claim 1, further comprising at least one potted in cable box to protect and house the connections between the solar cells system and the outlet conducting cables.

9. The solar panel of claim 1, wherein the panel comprising a permanent, rigid or flexible but thin (<1-3 mm) substrate.

10. The solar panel of claims 1 and 9, wherein the solar panel is flexible itself and is configured to be bent in any direction and to be attached to moderately curved surfaces.

11. The solar panel of claim 1, wherein the solar panel comprising a thin U-shaped edge frame, surrounding the edges of the panel and encapsulated with the solar cell system as required by panel design.

12. The solar panel of claim 11, wherein the encapsulated, thin, U-shaped edge frame is of non-corroding metal or plastic.

13. The solar panel of claim 1, further comprising a plurality of plastic or corrosion-resistant metal grommets that may be built into the corners and/or edges of the panel.

14. The solar panel of claims 1, wherein the functional lifespan of all the materials used in the solar panel is more than 10 years in portable or semi-portable applications.

15. A method for manufacturing the solar panel of claim 1, comprising:
encapsulating the solar cells system onto a temporary substrate (for a solar panel without substrate) or a permanent substrate (for a solar panel with substrate) by potting or lamination in encapsulating material, wherein the encapsulating material is a UV/weather-resistant, flexible, and clear polyurethane polymer or similar materials with similar functions and benefits.

16. The potting method of claim 15 further comprising:
pre-degassing polyurethane by heating and vacuuming before potting for removing moisture inside the polymer fluids;
vacuuming the potted solar panel to bring the air trapped under the solar cells and inside the polyurethane to the top surface right after potting, and then bubble picking;
further bubbles picking after brief higher temperature (60° C.) accelerated partial gelling of the potted solar panel before complete gelling and curing at lower temperature (40° C.) heating.

17. An integrated solar power generation and supply system, comprising:
a plurality of solar panels which are connected together in series and/or parallel,
at least one solar charger controller and/or inverter,
one or more energy storage devices, wherein the solar panels are electrically coupled with solar controller/inverter and energy storage devices for solar energy storage or to supply power directly to relevant devices/equipment.
